(19) United States
(12) Patent Application Publication
(10) Pub. No.: US 2012/0305892 A1
(43) Pub. Date: Dec. 6, 2012

(54) ELECTRONIC DEVICE, METHOD OF MANUFACTURING A DEVICE AND APPARATUS FOR MANUFACTURING A DEVICE

(76) Inventors: Martin Thornton, Grenoble (FR); Nikolay Nikolaevich Iosad, Geldrop (NL)

(21) Appl. No.: 13/314,613

(22) Filed: Dec. 8, 2011

Related U.S. Application Data
(60) Provisional application No. 61/421,086, filed on Dec. 8, 2010.

(51) Int. Cl. H01L 51/30; H01L 21/306; H01L 51/40; B82Y 30/00

(52) U.S. Cl. 257/29; 257/40; 438/99; 438/151; 156/345.3; 257/E51.006; 977/734; 977/742

(57) ABSTRACT

An electronic device comprises an in-plane component formed in an organic semiconductor layer, desirably graphene, on a flexible substrate. The component is formed using imprint lithography to create a trench through the organic semiconductor layer in a roll-to-roll process. The number of process steps required is limited to allow manufacture of the device in a single integrated apparatus.

### FIELD

The present invention relates to an electronic device, in particular an in-plane electronic device formed, on a flexible substrate, to a method of manufacturing such a device and to apparatus for manufacturing such a device.

### BACKGROUND

A standard technique for manufacture of integrated circuits is optical lithography in which complex devices are manufactured on rigid substrates, usually substrates of silicon. A large number of exposures are used to form multiple patterned layers to create the functioning devices. Although optical lithography is highly successful as a technique, it is desirable to create electronic devices on flexible substrates and at lower cost.

To this end, various proposals for in-plane components, in which all the parts of a component are in a single plane, have been made. Some examples of publications describing in-plane devices include:
J. Nieder et al. Appl. Phys. Lett, 57 (25) 2695 (1990) disclose using an electron beam to define a pattern and reactive ion etching (RIE) to etch isolation trenches in a GaAlAs layer to form an in-plane field effect transistor (FET).
S. Luscher et al. Appl. Phys. Lett, 75 (16) 2452 (1999) disclose use of an atomic force microscope to form oxidized lines in a GaAlAs structure (the oxide was used as the device dielectric) to form an in-plane FET.
A. D. Wieck et al. Appl. Phys. Lett, 56 (10) 928 (1990) disclose use of focused ion beam lithography to etch trenches to isolate gates from the semiconductor structure to form an in-plane FET.
European patent application publication no. EP 1,380,053 discloses the use of nano-embossing to imprint in-plane organic semiconductors.
A. M. Song et al. Appl. Phys. Lett, 83 (9) 1881 (2003) discloses in-plane diodes formed in a 2D material system (In_{0.75}Ga_{0.25}As/InP) using e-beam lithography and wet etching to pattern and define the diodes. The diodes operate at 4.2K rather than room temperature.
J. H. Chen et al. Adv. Mater, 19 3623 (2007) discloses graphene-based circuitry (specifically FETs) fabricated from mechanically exfoliated graphene using transfer printing to PET foil.
S. Wang et al. Nano Lett., 10 92 (2010) and PCT patent application publication no. WO2009/099707 disclose all carbon FETs (carbon source drain electrodes) with graphene active layers fabricated on Si/SiO₂ from graphene which was printed via a solution-based, process.

### SUMMARY

So-called roll-to-roll (R2R) manufacturing processes have been developed to provide lower cost manufacturing of electronic devices. For example, the Hewlett-Packard Development Company, L.P. Self-Aligned Imprint Lithography (SAIL) process is aimed at production of displays. A main disadvantage of the SAIL process is that it is a subtractive process, where an imprint process is employed to create a multilevel etch mask. Plastic Logic Ltd of Cambridge, United Kingdom, has developed off-set printing solutions for RFID R2R printing. Registration and ink-related issues result in a very low switching speed of printed transistors, caused by low mobility of charge carriers and/or large dimensions of printed structures.

In-plane electronic devices with improved properties and methods and apparatus for manufacturing them are desirable.

According to an aspect, there is provided an electronic device comprising: a flexible substrate; an organic semiconductor layer disposed on the flexible substrate; and an in-plane component defined in the organic semiconductor layer by imprint lithography.

According to an aspect, there is provided a method of manufacturing an electronic component, the method comprising: providing a flexible substrate having thereon an organic semiconductor layer and an imprint resist layer; patterning the imprint resist layer using an imprint template; curing the patterned imprint resist layer; and transferring the pattern into the organic semiconductor layer to form an in-plane component.

According to an aspect, there is provided an apparatus to manufacture a device, the apparatus comprising:

a first coating device configured to coat an organic semiconductor layer onto a flexible substrate;

a second coating device configured to coat an imprint resist onto the organic semiconductor layer;

an imprint device configured to imprint a pattern into the imprint resist;

a pattern transfer device configured to transfer the pattern imprinted in the resist into the organic semiconductor layer; and

a web feed system configured to feed a continuous web sequentially past the first coating device, the second coating device, the imprint device and the pattern transfer device.

### BRIEF DESCRIPTION OF THE DRAWINGS

Embodiments of the present invention will be described further below with reference to exemplary embodiments and the accompanying drawings, in which:

FIG. 1 is a schematic view of an FET according to an embodiment of the present invention;

FIG. 2 is a cross-sectional view of the FET of FIG. 1 along the line A-A;

FIGS. 3 to 8 illustrate steps in a device manufacturing method according to an embodiment of the present invention;

FIGS. 9 to 13 illustrate steps in a device manufacturing method according to an embodiment of the present invention;

FIGS. 14 and 15 illustrate steps in a variant of the device manufacturing method of FIGS. 9 to 13;

FIGS. 16 to 18 illustrate steps in a method of adding additional conductive components to a device according to an embodiment of the present invention;

FIG. 19 is a plan view of an antenna included in a device according to an embodiment of the present invention;

FIG. 20 is a cross-sectional view of the device of FIG. 19 along the line A-A;

FIG. 21 illustrates an apparatus to perform a method of manufacturing a device according to an embodiment of the invention; and

FIG. 22 illustrates structures of some materials usable in embodiments of the invention.

### DETAILED DESCRIPTION

The present invention is described below with reference to exemplary embodiments which are not to be considered limiting of the invention. In the description below, like parts are indicated by like references.

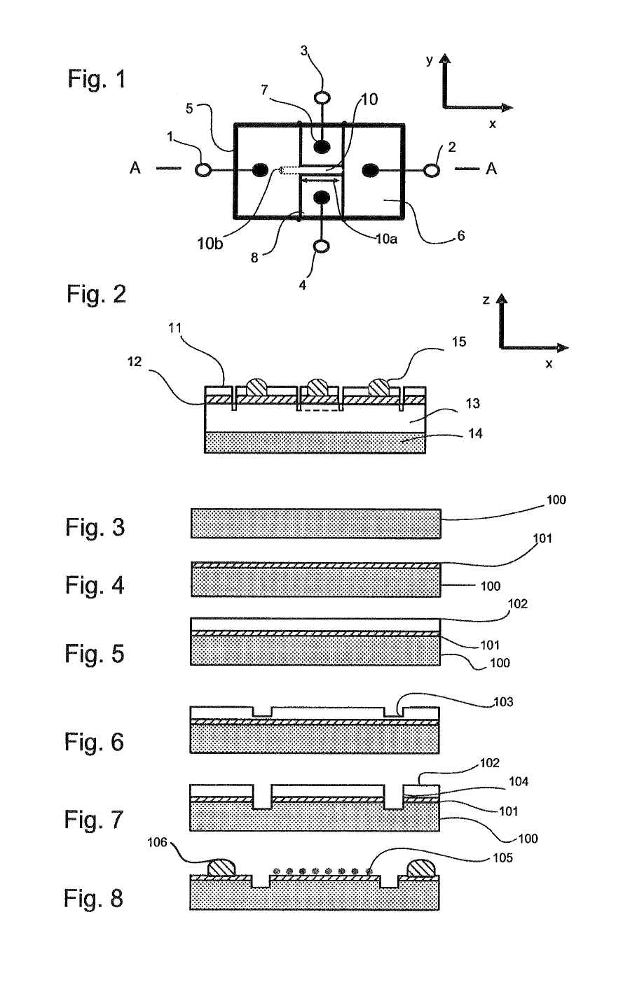

FIG. 1 shows a dual gate in-plane FET which comprises four semiconducting islands 5, 6, 7, 8 which are defined by creating trenches in an organic semiconductor, e.g. graphene, layer 12, as shown in FIG. 2. Island 5 forms the source of the FET while island 6 forms the drain, island 7 forms a first gate and island 8 forms a second gate. Channel 10 lies between the two gates and connects source 5 and drain 6. Channel 10 has length 10a and width 10b. Terminals 1, 2, 3 and 4 provide connections to the source, drain, first gate and second gate.

FIG. 2 shows a cross-section of the device which is formed on a flexible substrate 14 on which is provided an optional insulating layer 13. On the insulating layer or the substrate is organic semiconductor layer 12. In the embodiment described below, layer 12 is formed of graphene. In other embodiments it can be formed of carbon nanotubes, a polycyclic aromatic hydrocarbon (PAH) including benz[d]ovalene 501, coronene 502, naphthacene 503, chrysene 504, ovalene 505, triphenylene 506, corannulene 507, anthracene 508, pentacene 509, benzo[a]pyrene 510, pyrene 511 and benz[a]ovalene 512. Structures of these compounds are shown in FIG. 22. Derivatives of these compounds can also be used. Graphene layer 12 can be deposited by friction, by a solution-based process, by transference printing, by an electrostatic process or grown from a precursor. A method of forming such a graphene layer is described in A. Ismach et al Nano. Lett, 10 1542 (2010), which document is incorporated herein in its entirety by reference. The trenches or slits between the islands can be formed by imprint lithography and plasma etching or glow discharge as described further below. An imprint layer (resist) 11 can remain on top of the created device or be stripped. Conductive contacts 15 to form terminals 1 to 4 can be formed by inkjet printing using a solution that dissolves the imprint layer and then dries to form a conductive contact.

In embodiments of the present invention, the FET shown in FIGS. 1 and 2 can have various different properties according to whether the graphene layer 12 is N or P doped and by selecting the dimensions of the channel 10, in particular its width 10b. Applying a bias voltage to one or both terminals 3 and 4 results in current through the channel 10 being pinched off at a defined voltage. It should be noted that FIGS. 1 and 2 are not drawn to scale. The width 10b and length 10a of the channel 10 can be in the range of from 10 nm to 100 μm. Also, although the inkjet printed features 15 are shown as only a little bigger than the slits defining the device, these features can in fact be several orders of magnitude larger.

A method of forming the device of FIGS. 1 and 2 is shown step-by-step in FIGS. 3 to 8. In a first step, FIG. 3, a non-rigid substrate 100 (comprising the substrate 14 and insulating layer 13 if used) is provided. In the second step, FIG. 4, a graphene layer 101 is deposited by friction, by a solution-based process, by transference printing, by an electrostatic process or by being grown from a precursor. Next, FIG. 5, an imprint layer 102 is coated on the graphene layer by any suitable known process. The imprint layer is patterned, FIG. 6, by an imprinting step using an imprint template. In an embodiment, the imprinting is performed by a cylindrical transparent roller (as the imprint template) having the desired pattern etched into its outer surface. As the substrate passes over the roller (or vice versa) portions 103 of the imprint layer are displaced by projections in the imprint roller and taken up by recesses in the roller. A radiation source output, e.g. of DUV radiation, in the center of the roller cures the imprint layer so that it retains the imprinted shape after the substrate is peeled away from the imprint roller. A release coating can be applied to the roller prior to it being brought into contact with the imprint layer to avoid damage to the imprinted pattern when the substrate is peeled off the roller. In another embodiment, the imprinted pattern is applied via a stamp process.

After the imprint layer has been patterned, an etch process is carried out, FIG. 7, to form non-conducting slits 104 through the graphene layer 101, in order to form the isolated semiconductor islands of the device. The etch process can be an atmospheric oxygen plasma etch or a low pressure discharge process.

To complete the device, FIG. 8, the imprint layer 102 can be removed and the graphene doped 105 locally or globally. Suitable methods of doping the graphene include exposure to plasma, absorption of metallic (e.g. Ag), magnetic or semiconducting atoms or molecules (such as F4TCNQ), deposition of nanoparticles via evaporation, a solution-based process as spin coating, spray coating or blade coating, and/or inkjet printing. In this way, the graphene can be made P or N doped locally or globally. Ohmic contacts 106 to the graphene can be made by inkjet printing.

The above described method is desirably performed as a roll-to-roll (R2R) method, whereby the steps are performed in turn on a continuous web that moves past respective devices to perform the method steps. In this way, large numbers of devices can be manufactured at high speed. The small number of steps required in embodiments of the invention allows the method to be performed in a single pass through an integrated machine. The need to wind the web up on a roll, transfer to another machine and unwind can be avoided. This reduces processing time and avoids problems that might arise due to mis-registration between processes performed by different machines.

Devices according to an embodiment of the invention can be radio frequency identification (RFID) devices (tags), displays, logic, etc. Devices according to an embodiment of the invention can be based on PMOS, NMOS and/or CMOS construction principles.

In a first (not illustrated) variant on the above method, the imprint pattern is provided with an array of projections such that when the film layers are etched, in addition to the non-conducting slits to define the semiconductor islands, an array of periodic holes is formed in the graphene. The array of holes can be formed in selected areas only or across the entire area of the graphene layer. The size and spacing of the holes is chosen to create a band gap as described in J. Bai et al, Nature Nanotechnology, 5 190 (2010), which document is incorporated herein in its entirety by reference.

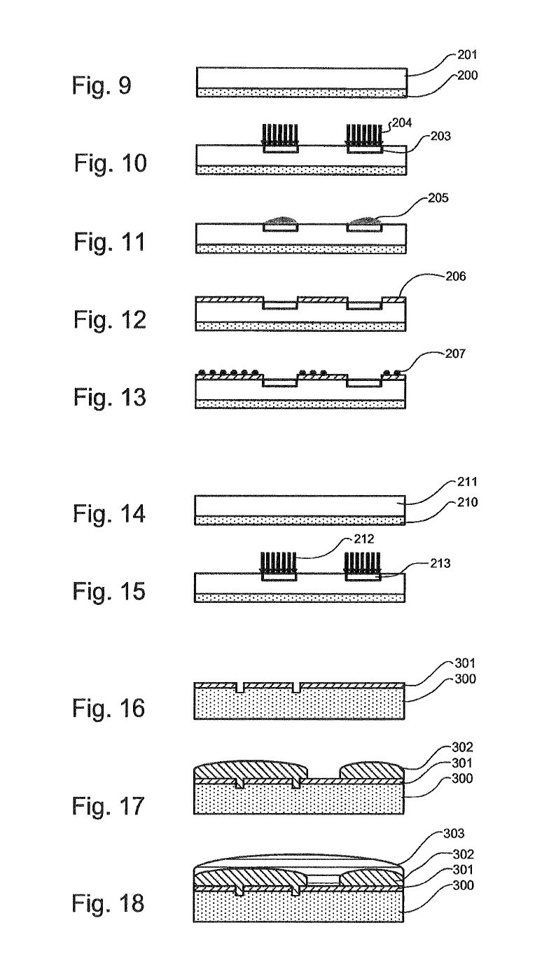

A device manufacturing method according to a further embodiment of the invention is now described with reference to FIGS. 9 to 13. In a first step, FIG. 9, a substrate 200 is coated with a patternable layer 201. The patternable layer 201 is formed from a material whose wetting properties are altered by exposure to radiation, e.g. light, an ion beam or an electron beam above a threshold fluence. For example, the material can be made more lyophilic (e.g., hydrophilic) by exposure to radiation. The material can be inorganic, organic or an organic-inorganic hybrid. Suitable materials include ZNO nanorods, poly (n-isopropylacrylimide)—commonly referred to as poly (NIPAAm) or poly (allylamine hydrochloride) or SiO₂ nanoparticles. Properties of some of these materials are described in T. Sun et a.l Angew. Chem. Int. Ed, (43) 357 (2004) and H. S. Lim et al. J. Am. Chem. Soc (129) 4128 (2007), which documents are incorporated herein in their entirety by reference. As shown in FIG. 10, the patternable layer 201 is exposed to a patterned beam of radiation 204 so as to form modified regions 203. As shown in FIG. 11, graphene 205 is applied via a solution based process such as inkjet printing or spray coating. Alternatively, a precursor solution from which graphene is grown can be applied. In either case, the areas on which the graphene layer 206 is formed are controlled by the exposure step of FIG. 10.

The graphene layer can be doped by any of the methods described above. An array of holes to control the band gap can also be formed as described above by providing different dopants in different regions—N and P type thin film transistors (TFT) can be formed in one layer. Ohmic contacts 207 to the graphene can be fabricated by inkjet printing or evaporation to realize the final device, as shown in FIG. 13.

In an alternative to the above method, a radiation sensitive graphene layer 211 is deposited on flexible substrate 210, FIG. 14. In FIG. 15, the graphene layer 211 is irradiated by radiation 212 having a fluence above a certain intensity sufficient to alter the properties of the grapheme 213. The radiation can be electromagnetic radiation (e.g. DUV), an ion beam, or an electron beam.

FIGS. 16 to 18 illustrate a method for manufacturing interconnects, jumpers, antennas and other large-scale conductive components. This method can be applied to devices created by any of the above methods, or other methods. FIG. 16 shows the flexible substrate 300 having a graphene layer 301 in which devices are defined. As shown in FIG. 17, an insulating layer 302 is selectively deposited over the graphene layer by inkjet or other suitable printing process. Openings are left where contact to the graphene layer is desired. As shown in FIG. 18, conductive layer 303 is printed in the design pattern, making contact through the openings in the insulating layer 302 to the graphene layer 301. The conductive layer can provide interconnects between different parts of a device, antenna (e.g. for a RFID device), printed jumpers and terminals, for example.

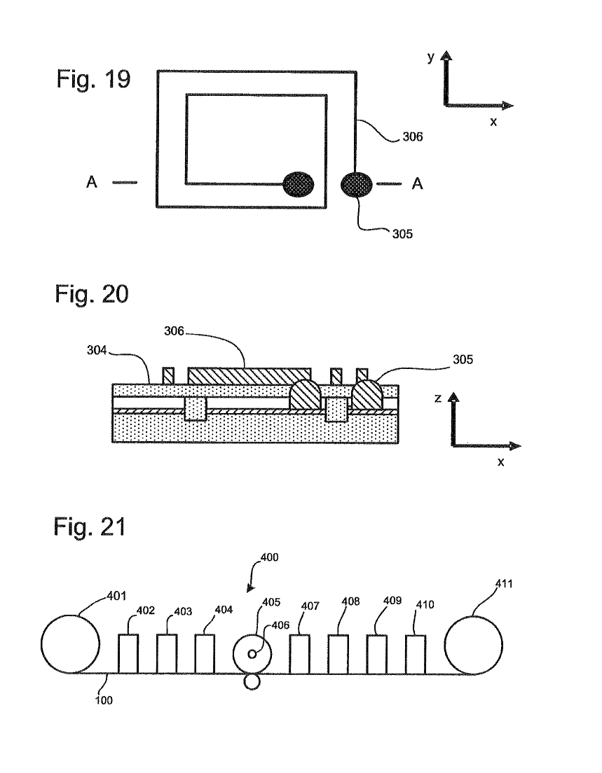

In an alternative method of manufacturing interconnects, jumpers, antennas and the like, an impermeable intermediate layer 304 is deposited on top of the graphene device layer. A device manufactured by this method is shown in FIGS. 19 and 20. Suitable methods for depositing the intermediate layer 304 include evaporation, a solution-based method such as spin coating, spray coating or blade coating, and/or a printing method such as offset, flexo printing, inkjet printing, etc. The intermediate layer is removed or its properties are changed from impermeable to permeable in the locations where jumpers or interconnects are to be defined. For simple applications such as RFID and other disposable electronics design, the alignment of this layer is not critical so that the openings for electrical contacts in this layer can be defined very coarsely. A metallic nanoparticle ink solution 305 is printed onto the intermediate insulating layer to define the jumper between the graphene circuitry and the RF antenna 306. The composition of the nanoparticle solution is such that it dissolves both the intermediate layer and the imprint layer and forms an ohmic contact to the graphene circuitry. The metallic nanoparticles are fused firmly or by irradiation by radiation above a certain fluence. In this way the final antenna is defined.

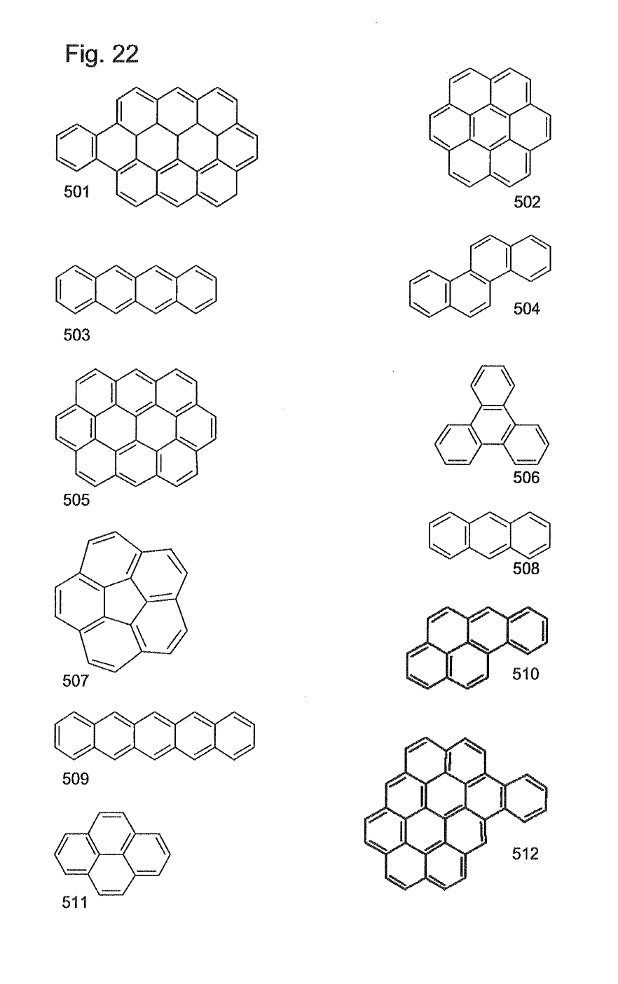

An apparatus 400 for use in the methods described above is shown in FIG. 21. The substrate 100 is fed from supply roll 401 past first coating station 402 which applies an insulating layer, second coating station 403 which applies the organic semiconductor layer and third coating station 404 which applies the imprint layer. The first coating station can be omitted if the insulating layer is not used. Imprint roller 405 imprints the desired pattern into the imprint layer and radiation output 406 (being or connected to a radiation source) cures the patterned imprint layer. Imprint roller 405 can be provided with a coating station to apply a release coating, a cleaning station to remove any imprint layer material that might stick to the roller, and an inspection station to monitor for defects in the pattern.

The imprinted substrate then passes to an etch station 407 to remove the undesired part of the organic semiconductor layer (using the patterned imprint layer), a doping station 408 to selectively dope parts of the pattern, an imprint layer stripping station 409 (if required) and a printing station 410 which prints conductive traces, etc. Take up roll 411 receives the completed substrate. Additional rollers, motors and sensors forming a web feed system can be provided to control movement of the continuous web forming the flexible substrate but are not shown. It will be appreciated that if additional steps are required, additional stations can be provided at appropriate positions on the line. Instead of a take up roll, a cutter can be provided to cut the substrate into separate devices.

As will be appreciated, any of the above described features can be used with any other feature and it is not only those combinations explicitly described which are covered in this application.

Although specific reference may be made in this text to the use of lithographic apparatus in the manufacture of ICs, it should be understood that the lithographic apparatus described herein may have other applications in manufacturing components with microscale, or even nano scale features, such as the manufacture of integrated optical systems, guidance and detection patterns for magnetic domain memories, flat-panel displays, liquid-crystal displays (LCDs), thin-film magnetic heads, etc.

The terms “radiation” and “beam” used herein encompass all types of electromagnetic radiation, including ultraviolet (UV) radiation (e.g. having a wavelength of or about 365, 248, 193, 157 or 126 nm), as well as particle beams such as ion beams and electron beams.

While specific embodiments of the invention have been described above, it will be appreciated that the invention may be practiced otherwise than as described. For example, the embodiments of the invention may take the form of a computer program containing one or more sequences of machine-readable instructions describing a method as disclosed above, or a data storage medium (e.g. semiconductor memory, magnetic or optical disk) having such a computer program stored therein. Further, the machine readable instruction may be embodied in two or more computer programs. The two or more computer programs may be stored on one or more different memories and/or data storage media.

The controllers described above may have any suitable configuration for receiving, processing, and sending signals. For example, each controller may include one or more processors for executing the computer programs that include machine-readable instructions for the methods described above. The controllers may also include data storage medium for storing such computer programs, and/or hardware to receive such medium.

The descriptions above are intended to be illustrative, not limiting. Thus, it will be apparent to one skilled in the art that modifications may be made to the invention as described without departing from the scope of the claims set out below.

1. An electronic device comprising:
a flexible substrate;
an organic semiconductor layer disposed on the flexible substrate; and
an in-plane component defined in the organic semiconductor layer by imprint lithography.

2. The electronic device according to claim 1, wherein the organic semiconductor layer is formed of at least one material selected from the group consisting of:
graphene;
carbon nanotubes; and
a polycyclic aromatic hydrocarbon.

3. The electronic device according to claim 2, wherein the organic semiconductor layer is formed of a polycyclic aromatic hydrocarbon and the polycyclic aromatic hydrocarbon is at least one material selected from the group consisting of:
benz[d]ovalene, coronene, naphthacene, chrysene, ovalene, triphenylene, corannulene, anthracene, pentacene, benzo[a]pyrene, pyrene and benz[a]ovalene.

4. The electronic device according to any of the preceding claims, wherein the in-plane component is a field effect transistor.

5. The electronic device according to claim 4, wherein the field effect transistor comprises first, second, third and fourth regions defined in the organic semiconductor layer, the first and second regions being connected by a channel passing between the third and fourth regions.

6. The electronic device according to claim 5, wherein the third and fourth regions are electrically isolated from the first and second regions by a trench etched in the organic semiconductor layer.

7. The electronic device according to any of the preceding claims, further comprising:
an insulating layer over the organic semiconductor layer; and
a conductive component printed on the insulating layer.

8. The electronic device according to claim 7, wherein the insulating layer is an imprint resist layer.

9. The electronic device according to claim 7 or claim 8, wherein the conductive component is a component selected from the group consisting of: an interconnects, an antenna (e.g. for a RFID device), a printed jumper and a terminal.

10. The electronic device according to any of the preceding claims, wherein the in-plane component is a PMOS, NMOS or CMOS component.

11. An RFID device including an electronic device according to any of the preceding claims.

12. A display device including an electronic device according to any of the preceding claims.

13. A method of manufacturing an electronic component, the method comprising:
providing a flexible substrate having thereon an organic semiconductor layer and an imprint resist layer;
patterning the imprint resist layer using an imprint template;
curing the patterned imprint resist layer; and
transferring the pattern into the organic semiconductor layer to form an in-plane component.

14. The method according to claim 13, wherein transferring the pattern comprises etching the organic semiconductor layer to form a trench therein.

15. The method according to claim 13 or claim 14, wherein the steps of the method are performed sequentially on a continuous web.

16. The method according to claim 15, wherein the steps of the method are performed on a single integrated apparatus.

17. The method according to any of claims 13 to 16, wherein the organic semiconductor layer is formed of a material selected from the group consisting of:
graphene;
carbon nanotubes; and
a polycyclic aromatic hydrocarbon.

18. The method according to claim 17, wherein the organic semiconductor layer is formed of a polycyclic aromatic hydrocarbon and the polycyclic aromatic hydrocarbon is at least one material selected from the group consisting of:
benz[d]ovalene, coronene, naphthacene, chrysene, ovalene, triphenylene, corannulene, anthracene, pentacene, benzo[a]pyrene, pyrene and benz[a]ovalene.

19. The method according to any of claims 13 to 18, wherein the in-plane component is a field effect transistor.

20. The method according to claim 19, wherein the field effect transistor comprises first, second, third and fourth regions defined in the organic semiconductor layer, the first and second regions being connected by a channel passing between the third and fourth regions.

21. The method according to claim 20, wherein the third and fourth regions are electrically isolated from the first and second regions by a trench etched in the organic semiconductor layer.

22. The method according to any of claims 13 to 21, wherein the in-plane component is a PMOS, NMOS or CMOS component.

23. An apparatus to manufacture a device, the apparatus comprising:
a first coating device configured to coat an organic semiconductor layer onto a flexible substrate;
a second coating device configured to coat an imprint resist onto the organic semiconductor layer;
an imprint device configured to imprint a pattern into the imprint resist;
a pattern transfer device configured to transfer the pattern imprinted in the resist into the organic semiconductor layer; and
a web feed system configured to feed a continuous web sequentially past the first coating device, the second coating device, the imprint device and the pattern transfer device.
